(19) United States
(12) Patent Application Publication
(10) Pub. No.: US 2014/0342475 A1
(43) Pub. Date: Nov. 20, 2014

(54) SEMICONDUCTOR TEST METHOD AND SEMICONDUCTOR TEST APPARATUS

(71) Applicant: KABUSHIKI KAISHA TOSHIBA, Tokyo (JP)

(72) Inventors: Kenichi MIKI, Hyogo (JP); Keiji MORINO, Hyogo (JP)

(73) Assignee: KABUSHIKI KAISHA TOSHIBA, Tokyo (JP)

(21) Appl. No.: 14/194,400

(22) Filed: Feb. 28, 2014

(30) Foreign Application Priority Data
May 17, 2013 (JP) 2013-105544

(51) Int. Cl. H01L 21/66; H01L 21/67; G01R 31/26; H01L 21/78

(52) U.S. Cl. CPC H01L 22/14; H01L 21/78; H01L 21/67011; G01R 31/2601
USPC 438/15; 324/762.03

(57) ABSTRACT

A semiconductor test method includes attaching a sheet to a wafer on which a plurality of chips are formed, the sheet having a plurality of holes, each of which corresponds to a position of one of the chips, dicing the wafer to separate the plurality of chips into individual chips while the sheet remains attached to the individual chips, and after the dicing and while the sheet remains attached to the individual chips, measuring the electrical characteristics of the chips.

### CROSS-REFERENCE TO RELATED APPLICATION

This application is based upon and claims the benefit of priority from Japanese Patent Application No. 2013-105544, filed May 17, 2013, the entire contents of which are incorporated herein by reference.

### FIELD

Embodiments described herein relate generally to semiconductor test methods and semiconductor test apparatuses for measuring various electrical characteristics of semiconductor chips by bringing probes into contact with the semiconductor chips.

### BACKGROUND

On a semiconductor wafer, a number of semiconductor chips are formed. Conventionally, after the electrical characteristics of individual chips on the wafer are measured, the wafer is diced into the individual chips.

Electrical measurement of chips before dicing has an advantage in that probes can be accurately brought into contact with selected points on a chip to be measured. However, when dicing is performed after the electrical characteristics measurement, damage during dicing may give rise to a new defect. Thus a chip that is a non-defective product in a wafer state may become faulty after dicing, causing a problem in that such a defect cannot be detected.

Moreover, when the thickness of a wafer is reduced to lower the on-resistance of chips, trouble in transportation is likely to occur due to warping of the wafer, and moreover, trouble such as cracking or chipping of the wafer is likely to occur during dicing.

Furthermore, when a test of dynamic electrical characteristics is performed in a wafer state, breakage of a chip during the test may affect a different chip, as the different chip may be damaged by the flow of a short-circuit current or the like.

### DESCRIPTION OF THE DRAWINGS

FIG. 1 is a diagram showing the arrangement of a flat ring and a dicing sheet used for dicing and testing of a wafer.

FIG. 2 is a diagram showing the wafer attached to the dicing sheet.

FIG. 3 is a perspective view showing the wafer attached to the dicing sheet through the flat ring and diced.

FIG. 4 is a view of the wafer taken from a horizontal direction.

FIG. 5 is a block diagram showing the schematic configuration of a semiconductor test system according to an embodiment.

FIG. 6 is a flowchart showing an example of process operations of the semiconductor test system shown in FIG. 5.

FIG. 7 is a block diagram showing an example of the internal configuration of a wafer attachment device.

FIG. 8 is a block diagram showing an example of the internal configuration of a dicing device.

FIG. 9 is a block diagram showing an example of the internal configuration of a measurement device.

FIG. 10 is a block diagram showing an example of the internal configuration of a mounting device.

FIG. 11 is a perspective view showing an example of probes being brought into contact with a plurality of chips on a wafer.

FIG. 12 is a view of the example in FIG. 11 taken from a horizontal direction.

### DETAILED DESCRIPTION

Embodiments provide a semiconductor test method and a semiconductor test apparatus which are capable of accurately measuring electrical characteristics of a plurality of chips formed on a wafer.

According to one embodiment, a semiconductor test method includes attaching a sheet to a wafer on which a plurality of chips are formed, the sheet having a plurality of holes, each of which corresponds to a position of one of the chips, dicing the wafer to separate the plurality of chips into individual chips while the sheet remains attached to the individual chips, and after the dicing and while the sheet remains attached to the individual chips, measuring the electrical characteristics of the chips.

Embodiments will be described below with reference to the drawings.

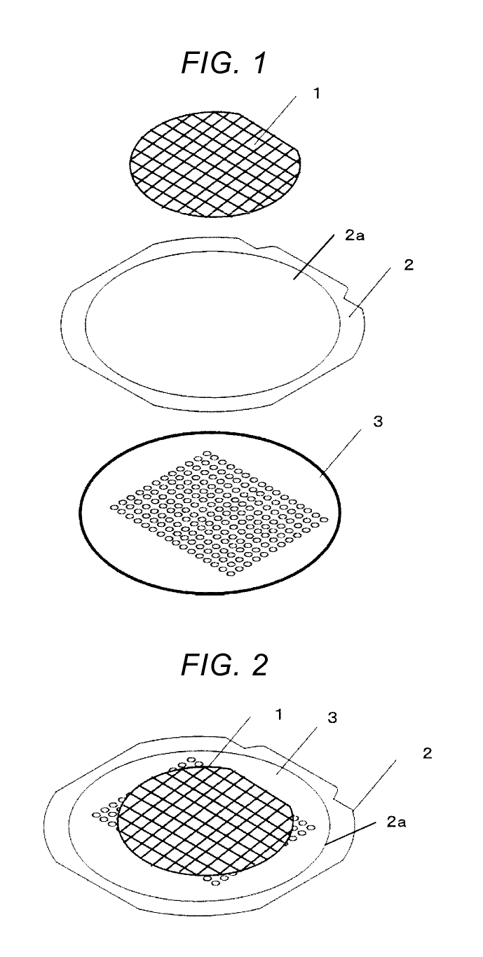

In an embodiment, a wafer on which a number of chips are formed is diced into pieces, and then an electrical characteristics test is performed. FIG. 1 is a diagram showing the arrangement of a flat ring (flat-shaped ring) 2 and a dicing sheet (insulating sheet) 3 used for dicing and testing of a wafer 1. As shown in the figure, the dicing sheet 3 is attached to the back side of the flat ring 2, and the wafer 1 is attached to the dicing sheet 3 from the top side of the flat ring 2 before dicing.

The flat ring 2 is a flat plate formed with an opening 2a at a central portion, the inside diameter of which is larger than the outside diameter of the wafer 1, and smaller than the outside diameter of the dicing sheet 3. The dicing sheet 3 is attached to the back side of the flat ring 2, and the portion of the dicing sheet 3 extending out from the outside diameter of the flat ring 2 is cut off as needed. The flat ring 2 is formed by a metal material such as stainless steel, for example.

The base material of the dicing sheet 3 is resin, for example. The dicing sheet 3 is made by attaching an adhesive or an ultraviolet-curable material to both surfaces of the resin base.

The dicing sheet 3 is formed with holes 3a corresponding to the positions of chips 4 on the wafer 1. That is, the dicing sheet 3 is formed with a plurality of holes 3a whose number is the same as the number of the chips 4 on the wafer 1. The holes 3a each have a diameter of a size that allows a probe of a tester to be brought into contact with the back surface of the wafer 1.

FIG. 2 is a diagram showing a state where the dicing sheet 3 is attached to the flat ring 2, and the wafer 1 is attached to the dicing sheet 3 through the opening 2a of the flat ring 2. As shown in the figure, the dicing sheet 3 is attached to the back side of the flat ring 2, so that the dicing sheet 3 is exposed from the opening 2a at the central portion of the flat ring 2. Through this exposed portion, the wafer 1 is attached to the dicing sheet 3 from above.

As described below, in the embodiment, with the wafer 1 attached to the dicing sheet 3 through the flat ring 2, the wafer 1 is diced. However, until the testing by the tester is completed, the individual chips 4 are not separated.

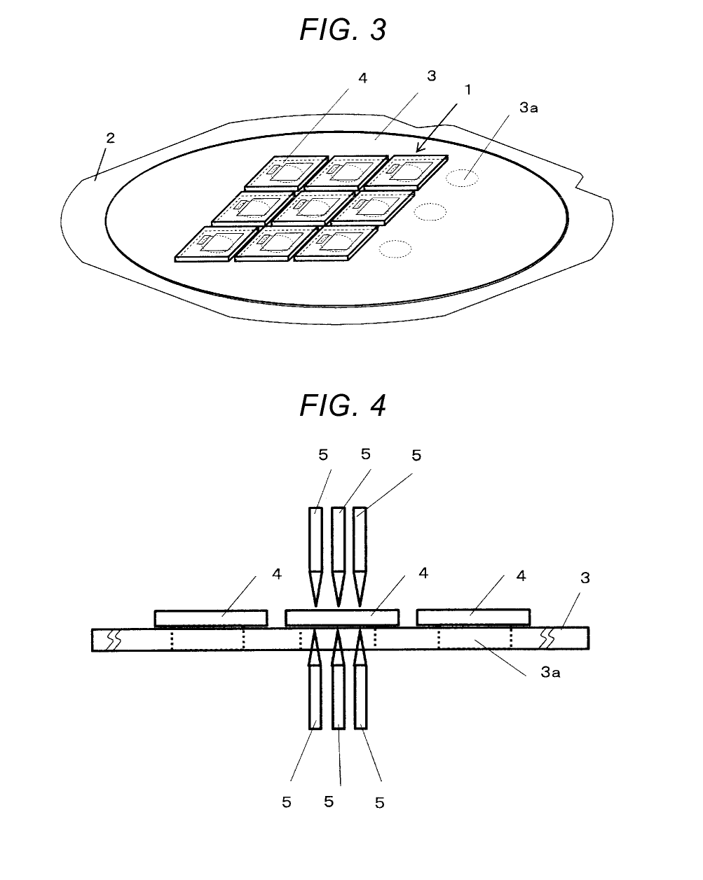

FIG. 3 is a perspective view showing the wafer 1 attached to the dicing sheet 3 through the flat ring 2 and diced. FIG. 4 is a view of the wafer 1 taken from a horizontal direction. As shown in these figures, the wafer 1 and the dicing sheet are positioned so that the holes 3a are located at approximately central portions of the chips 4, followed by dicing. Since the chips 4 are typically each formed at the back side with a ground pattern and a power source pattern over the entire surface, probes 5 brought into contact with the back surface of the chip 4 from the back side through the hole 3a can be connected to the ground pattern and the power source pattern. In order to accurately contact the position of a surface electrode, it is necessary to recognize the electrode position on the chip 4 through image processing and make a correction, and then accurately bring the probe 5 into contact with a point at which electrical characteristics are to be measured.

FIG. 4 shows an example of bringing three probes 5 into contact with each side of one of the chips 4. However, there is no particular limit on the number of the probes 5 to be brought into contact. When the electrical characteristics of a plurality of points on one of the chips 4 are to be measured simultaneously, a plurality of probes 5 in accordance with the number of points to be measured may be brought into contact with the chip 4.

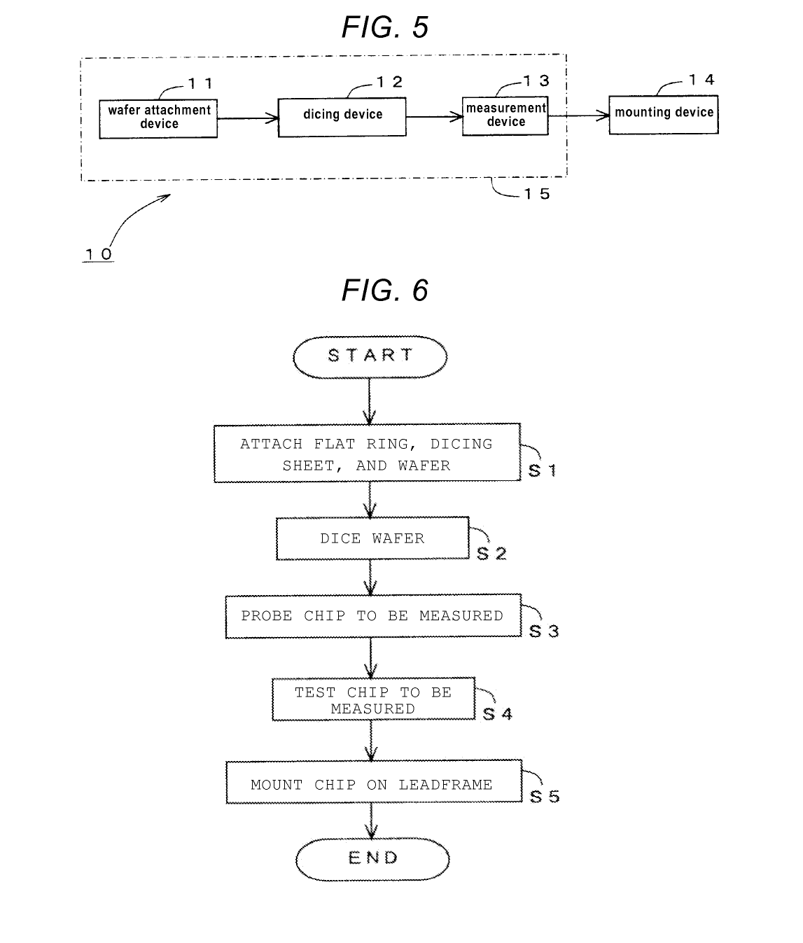

FIG. 5 is a block diagram showing the schematic configuration of a semiconductor test system 10 according to the embodiment. The semiconductor test system 10 in FIG. 5 includes a wafer attachment device 11, a dicing device 12, a measurement device 13, and a mounting device 14. Among these, except for the mounting device 14, the wafer attachment device 11, the dicing device 12, and the measurement device 13 constitute a semiconductor test apparatus 15.

The wafer attachment device 11 performs a process of positioning and attaching the dicing sheet 3 and the wafer 1 via the flat ring 2 as shown in FIGS. 1 and 2.

The dicing device 12 dices the wafer 1 attached to the dicing sheet 3 as shown in FIG. 3.

The measurement device 13 measures the electrical characteristics of the individual chips 4 in the wafer 1 attached to the dicing sheet 3 and diced.

The mounting device 14 mounts, on a circuit board, the non-defective chips 4 in the wafer 1 whose electrical characteristics measurements have been completed.

FIG. 6 is a flowchart showing an example of process operations of the semiconductor test system 10 in FIG. 5. First, using the wafer attachment device 11, the dicing sheet 3 is attached to the flat ring 2, and the wafer 1 is attached to the dicing sheet 3 exposed through the opening 2a at the central portion of the flat ring 2 (step S1). At this time, the holes 3a in the dicing sheet 3 are aligned with the corresponding chips 4 in the wafer 1, and the wafer 1 is attached to the dicing sheet 3.

Next, using the dicing device 12, the wafer 1 attached to the dicing sheet 3 is diced (step S2).

Next, using the measurement device 13, the probes 5 of the tester are connected to the chip 4 to be measured in the diced wafer 1 (step S3). At the top side of the chip 4 to be measured, the probes 5 are brought into contact with points to be measured, and at the bottom side of the chip 4 to be measured, the probes 5 are brought into contact with the lower surface of the chip 4 through the hole 3a in the dicing sheet 3, and then the electrical characteristics of the chip 4 to be measured are tested (step S4). The test results are stored as mapping data together with information about the positions of the chips 4.

Next, using the mounting device 14, the chips 4 are mounted on leadframes (step S5). The mapping data is referenced during the mounting of the non-defective chips 4.

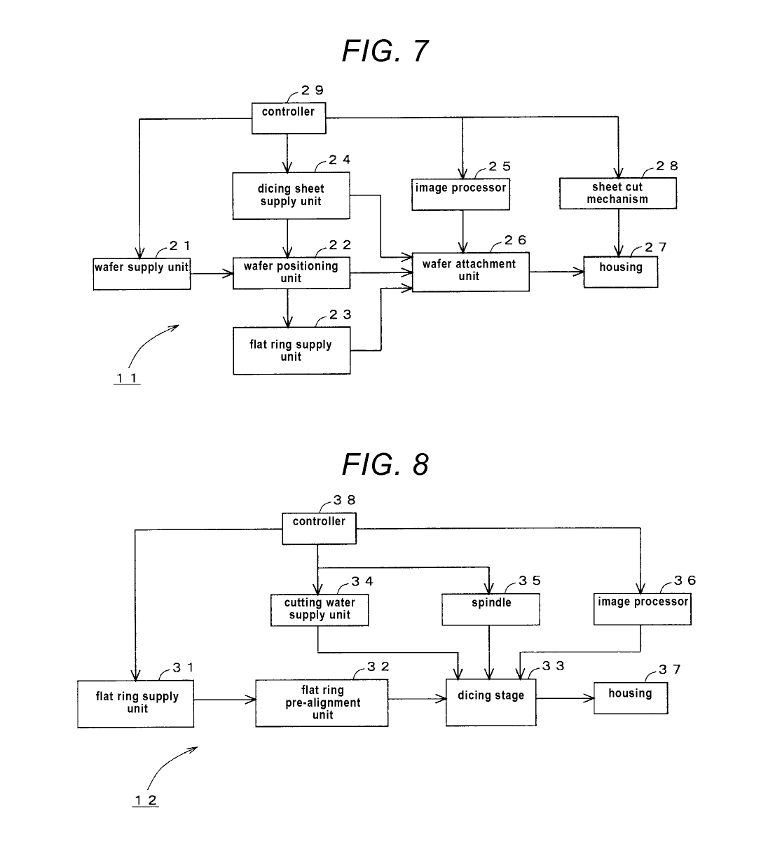

FIG. 7 is a block diagram showing an example of the internal configuration of the wafer attachment device 11. The wafer attachment device 11 in FIG. 7 includes the wafer supply unit 21, a wafer positioning unit 22, a flat ring supply unit 23, a dicing sheet supply unit 24, an image processor 25, a wafer attachment unit 26, a housing 27, a sheet cut mechanism 28, and a controller 29. The controller 29 controls each unit in the wafer attachment device 11.

The wafer supply unit 21 supplies the wafer 1 formed with the chips 4 on the entire surface and not diced yet. The wafer positioning unit 22 positions the wafer 1 supplied in a predetermined position.

The flat ring supply unit 23 supplies the flat ring 2 to be used in dicing and testing. When the wafers 1 have the same size, the flat ring 2 used previously can be used again.

The dicing sheet supply unit 24 supplies the new dicing sheet 3 in synchronization with timing with which the wafer supply unit 21 supplies the new wafer 1. A different dicing sheet 3 is necessary for each wafer 1.

The image processor 25 takes an image of the wafer 1, the flat ring 2, and the dicing sheet 3 supplied for positioning, and analyzes the image taken to detect the amount of misalignment. The wafer attachment unit 26 aligns the wafer 1 and the dicing sheet 3, checking the result of image processing by the image processor 25, and attaches the wafer 1 to the dicing sheet 3 through the flat ring 2.

The housing 27 houses the flat ring 2 to which the wafer 1 and the dicing sheet 3 are attached. At that time, the sheet cut mechanism 28 cuts off the edge of the dicing sheet 3 to the outside diameter of the flat ring 2.

FIG. 8 is a block diagram showing an example of the internal configuration of the dicing device 12. The dicing device 12 in FIG. 8 includes a flat ring supply unit 31, a flat ring pre-alignment unit 32, a dicing stage 33, a cutting water supply unit 34, a spindle 35, an image processor 36, a housing 37, and a controller 38. The controller 38 controls each unit in the dicing device 12.

The flat ring supply unit 31 takes out the flat ring 2 to which the wafer 1 and the dicing sheet 3 are attached from the housing 37, and supplies it to the flat ring pre-alignment unit 32.

The flat ring pre-alignment unit 32 positions the flat ring 2 to which the wafer 1 and the dicing sheet 3 are attached on the dicing stage 33.

The image processor 36 takes an image of the perimeter of the flat ring 2 on the dicing stage 33, and analyzes the image. The spindle 35 controls the travel of the dicing stage 33 based on the image processing result to precisely position the flat ring 2.

After the positioning, the wafer 1 attached to the dicing sheet 3 via the flat ring 2 is diced while water is supplied from the cutting water supply unit 34 to the flat ring 2 on the dicing stage 33. The wafer 1 diced is housed in the housing 37, remaining attached to the dicing sheet 3 and the flat ring 2.

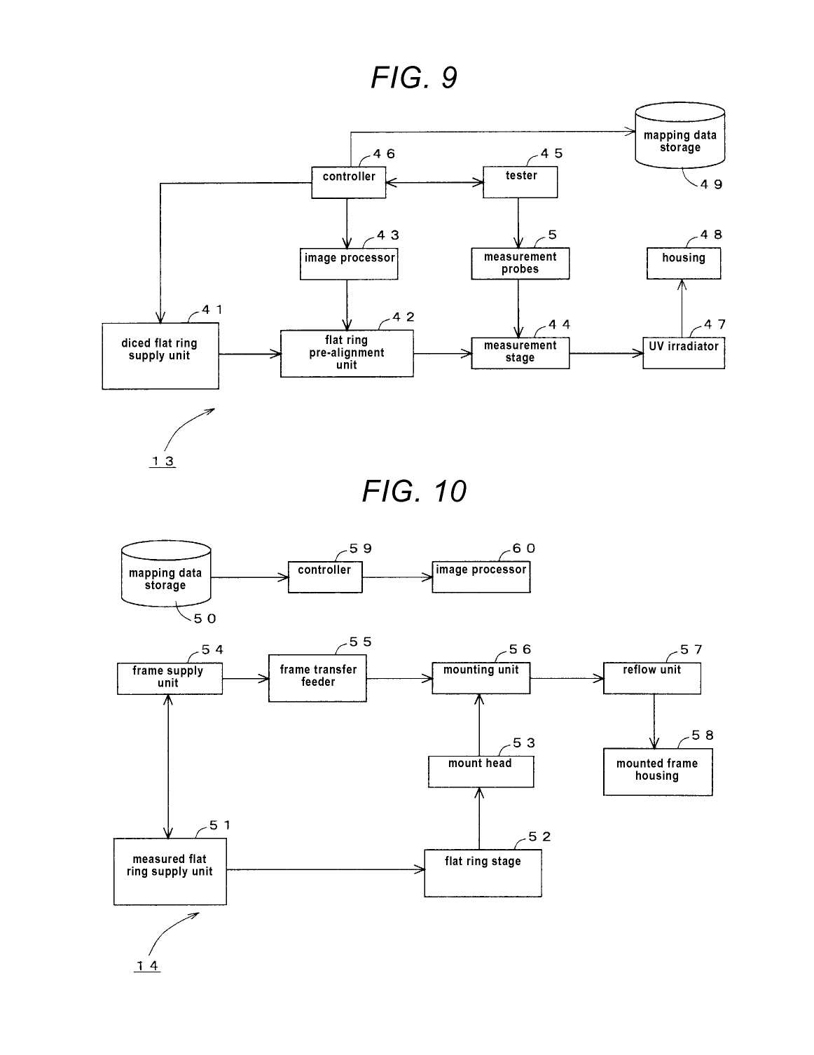

FIG. 9 is a block diagram showing an example of the internal configuration of the measurement device 13. The measurement device 13 in FIG. 9 includes a diced flat ring supply unit 41, a flat ring pre-alignment unit 42, an image processor 43, a measurement stage 44, the measurement probes 5, a tester 45, a controller 46, a UV irradiator 47, a housing 48, and a mapping data storage 49. The controller 46 controls each unit in the measurement device 13 in FIG. 9.

The diced flat ring supply unit 41 takes out the diced flat ring 2 housed in the housing 48 in FIG. 8, and supplies it to the flat ring pre-alignment unit 42.

The flat ring pre-alignment unit 42 positions the diced flat ring 2 on the measurement stage 44. Then, the image processor 43 takes an image of the measurement stage 44, analyzes the image taken, and detects the amount of misalignment relative to the position of a particular pad or pattern on the wafer 1. The measurement stage 44 is moved in accordance with the amount of misalignment to perform precise positioning.

When the positioning is completed, as shown in FIGS. 2 and 3, the probes 5 are brought, from above, into contact with particular points on the chip 4 to be measured in the wafer 1, while the probes 5 are brought, from below the flat ring 2, into contact with the ground pattern and the power source pattern on the lower surface of the chip 4 through the hole 3a in the dicing sheet 3.

Next, using the tester 45, the electrical characteristics of the chip 4 to be measured are measured. There is no restriction on the specific details of the electrical characteristics to be measured. For example, a static characteristics test and a dynamic characteristics test are performed on the chip 4 to be measured. The measured results of the chip 4 measured are stored as mapping data in the mapping data storage 49. The mapping data includes information about the position of the chip 4 measured on the wafer 1, and information indicating whether it is a non-defective product or not.

After measurement on one of the chips 4 to be measured is completed, the same measurement is performed on a different chip 4 to be measured. Mapping data on all the chips 4 in the wafer 1 is stored in the mapping data storage 49.

After completion of measurements of the electrical characteristics on all the chips 4 in the wafer 1, the UV irradiator 47 irradiates the dicing sheet 3 with ultraviolet light to reduce adhesion between the dicing sheet 3 and the wafer 1. The housing 48 houses the flat ring 2 after ultraviolet irradiation with the dicing sheet 3 and the wafer 1 remaining attached thereto.

FIG. 10 is a block diagram showing an example of the internal configuration of the mounting device 14. The mounting device 14 in FIG. 10 includes a measured flat ring supply unit 51, a flat ring stage 52, a mount head 53, a frame supply unit 54, a frame transfer feeder 55, a mounting unit 56, a reflow unit 57, a mounted frame housing 58, a controller 59, and an image processor 60. The controller 59 controls each unit in the mounting device 14 in FIG. 10.

The measured flat ring supply unit 51 takes out the measured flat ring 2 housed in the housing 48 in FIG. 9, and transfers it to the flat ring stage 52. The mount head 53 takes out the non-defective chip 4 from the wafer 1, based on the mapping data.

The frame supply unit 54 supplies a leadframe to be a base on which the chip 4 is placed. The frame transfer feeder 55 transfers the leadframe supplied from the frame supply unit 54 to the mounting unit 56.

The mounting unit 56 takes out the non-defective chip 4 from the wafer 1 mounted on the mount head 53, and mounts it on the leadframe.

The reflow unit 57 connects each pad on the chip 4 and the leadframe. The connected leadframe is stored in the mounted frame housing 58.

Thus, in a first embodiment, the dicing sheet 3 with the holes 3a bored in alignment with the positions of the chips 4 on the wafer 1 is prepared, the dicing sheet 3 is attached to the flat ring 2, the wafer 1 is diced, remaining attached in alignment with the holes 3a of the dicing sheet 3 exposed through the opening 2a of the flat ring 2, and then the probes 5 are brought into contact with both surfaces of the chip 4 to be measured on the wafer 1. More specifically, the probes 5 are brought into contact with the lower surface of the chip 4 to be measured through the hole 3a in the dicing sheet 3 to perform electrical characteristics measurement. With this, after the wafer 1 is diced, the electrical characteristics of all the chips 4 in the wafer 1 can be measured with the wafer 1 remaining bonded to the dicing sheet 3, thus eliminating the need to perform dicing after electrical characteristics measurement.

Moreover, the dicing sheet 3 is provided with the holes 3a corresponding to the positions of the chips 4 on the wafer 1, so that dicing and electrical characteristics measurement can be performed with the wafer 1 remaining attached to the dicing sheet 3, thereby reducing measurement time.

### Second Embodiment

Although in the first embodiment described above, an example of testing the individual chips 4 in the wafer 1 one after another is described, the plurality of chips 4 in the wafer 1 may be tested simultaneously in a range allowed by the positions of upper and lower electrodes.

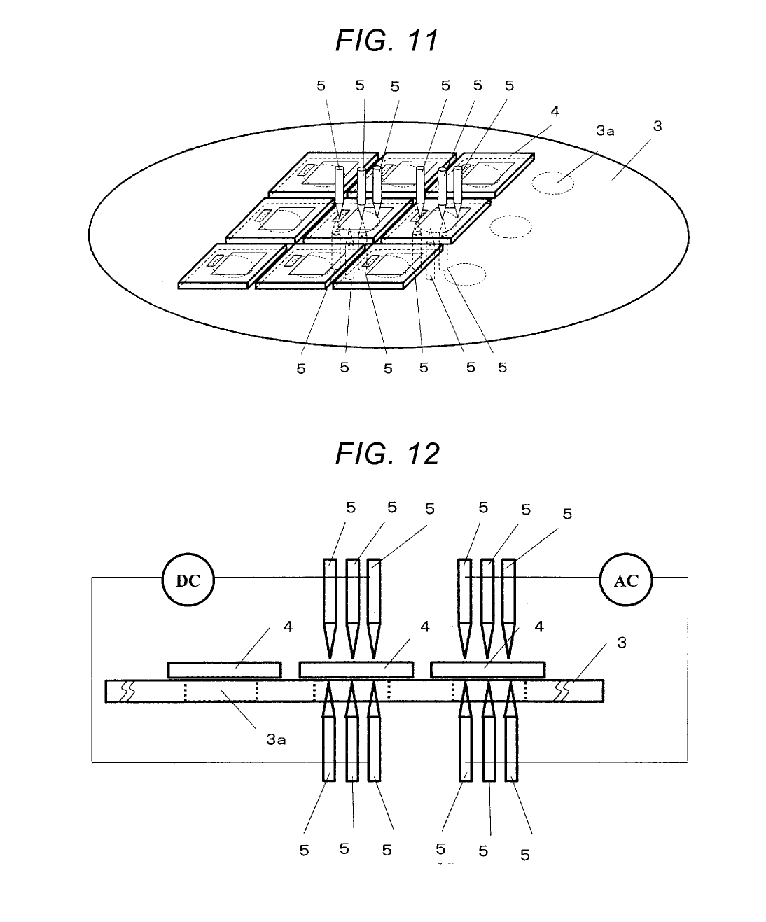

FIG. 11 is a perspective view showing an example of bringing probes 5 into contact with the plurality of chips 4 on the wafer 1. FIG. 12 is a view of this example taken from a horizontal direction.

At this time, the plurality of chips 4 contacted by the probes 5 may be measured for the same electrical characteristics or may be measured for different electrical characteristics. There is no particular limit on the number of chips 4 measured simultaneously.

Thus, the dicing sheet 3 is formed with the holes 3a corresponding to the chips 4 in the wafer 1, so that the electrical characteristics of the plurality of chips 4 can be measured simultaneously with probes 5 brought into contact with the plurality of chips 4 simultaneously in parallel, thereby improving measurement throughput.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor test method comprising:
attaching a sheet to a wafer on which a plurality of chips are formed, the sheet having a plurality of holes, each of which corresponds to a position of one of the chips;
dicing the wafer to separate the plurality of chips into individual chips while the sheet remains attached to the individual chips; and
after said dicing and while the sheet remains attached to the individual chips, measuring the electrical characteristics of the chips.

2. The semiconductor test method according to claim 1 wherein the sheet is attached to a back surface of a flat ring having an opening with a diameter larger than an outside diameter of the wafer, and the wafer is attached to the sheet through the opening.

3. The semiconductor test method according to claim 1, wherein
the electrical characteristics of one or more chips are measured by bringing probes into contact with surfaces of the chips.

4. The semiconductor test method according to claim 3, wherein the probes are brought into contact with upper and lower surfaces of the chips.

5. The semiconductor test method according to claim 4, wherein the probes are brought into contact with the lower surfaces of the chips through corresponding holes in the sheet.

6. The semiconductor test method according to claim 3, wherein the electrical characteristics of two or more chips are measured at the same time.

7. The semiconductor test method according to claim 3, further comprising:
aligning measurement points of the individual chips with respect to the probes prior to said measuring.

8. The semiconductor test method according to claim 7, wherein said aligning is performed using an image processor.

9. The semiconductor test method according to claim 1, further comprising:
aligning the holes of the sheet with respect to positions of the individual chips on the wafer prior to said attaching.

10. The semiconductor test method according to claim 9, wherein said aligning is performed using an image processor.

11. The semiconductor test method according to claim 1, further comprising:
removing the sheet after said measuring.

12. The semiconductor test method according to claim 11, wherein said removing includes irradiating the sheet with ultraviolet light.

13. A semiconductor test apparatus comprising:
a flat ring provided with an opening having a diameter larger than an outside diameter of a wafer;
a sheet having a diameter larger than the diameter of the opening, the sheet having a plurality of holes, each of which corresponds to a position of one of a plurality of chips formed on the wafer;
a support unit that supports the flat ring having the sheet attached thereto;
a cutter configured to cut the wafer supported by the support unit into individual chips without cutting the sheet; and
a measurement unit configured to measure the electrical characteristics of the individual chips.

14. The semiconductor test apparatus according to claim 13, further comprising:
an image processor configured to take an image of the wafer and the sheet, and determine an amount of misalignment of the holes with respect to positions of the chips on the wafer.

15. The semiconductor test apparatus according to claim 14, further comprising:
a wafer attachment unit configured to attach the wafer to the sheet based on the amount of misalignment determined by the image processor.

16. The semiconductor test apparatus according to claim 15, wherein the support unit comprises a dicing stage configured to position the wafer with respect to the cutter.

17. A semiconductor test apparatus comprising:
a wafer attachment unit configured to attach a wafer to a sheet through an opening of a flat ring that is also attached to the sheet, the sheet having a plurality of holes, each of which corresponds to a position of one of a plurality of chips formed on the wafer;
a support unit that supports the flat ring, the sheet attached to the flat ring, and the wafer attached to the sheet;
a cutter configured to dice the wafer supported by the support unit into individual pieces without cutting the sheet; and
a measurement unit configured to measure the electrical characteristics of the individual chips.

18. The semiconductor test apparatus according to claim 17, further comprising:
an image processor configured to take an image of the wafer and the sheet, and determine an amount of misalignment of the holes with respect to positions of the chips on the wafer.

19. The semiconductor test apparatus according to claim 18, wherein the wafer attachment unit is configured to attach the wafer to the sheet based on the amount of misalignment determined by the image processor.

20. The semiconductor test apparatus according to claim 17, wherein the support unit comprises a dicing stage configured to position the wafer with respect to the cutter.
